(19) United States
(12) Patent Application Publication
(10) Pub. No.: US 2008/0230848 A1
(43) Pub. Date: Sep. 25, 2008

(54) STRUCTURE HAVING DUAL SILICIDE REGION AND RELATED METHOD

(76) Inventors: Chih-Chao Yang, Glenmont, NY (US); Haining S. Yang, Wappingers Falls, NY (US); Keith Kwong Hon Wong, Wappingers Falls, NY (US)

Correspondence Address: HOFFMAN WARNICK LLC, 75 STATE ST, 14TH FL, ALBANY, NY, 12207, US

(21) Appl. No.: 11/689,708

(22) Filed: Mar. 22, 2007

(51) Int. Cl. H01L 29/76

(52) U.S. Cl. 257/388

(57) ABSTRACT

A structure including a dual silicide region and a related method are disclosed. The structure may include a doped silicon, and a dual silicide region in the doped silicon, the dual silicide region including a first silicide region including a mid band gap metal, and a second silicide region including a near band gap metal, wherein the second silicide region is immediately adjacent to the doped silicon. The method may include forming a first silicide portion in a doped silicon by depositing a first metal over the doped silicon, annealing and removing unreacted first metal; ion implanting a second metal into the doped silicon; and annealing to form a second silicide portion from the second metal, wherein the first metal is different than the second metal.

### BACKGROUND

1. Technical Field

The disclosure relates generally to integrated circuit (IC) fabrication, and more particularly, to a structure having a dual silicide region and a related method.

2. Background Art

In integrated circuit (IC) fabrication, external resistance of complementary metal-oxide semiconductor (CMOS) devices has become a major portion of the total series resistance. Higher resistances limit further device performance improvement as further miniaturization continues. One part of the external resistance is attributable to the contact resistance between metal silicide and doped silicon (e.g., in source/drain regions), which is determined by the band gap energy between the metal silicide and the silicon. Band gap energy is an energy amount separating a valance band and a conduction band of a material at which no electrons are permissible. Band gap energy is also referred to as a barrier height. Another part of the external resistance is the sheet (or bulk) resistance of the silicide at issue.

Currently used metals for silicide formation include, for example, cobalt (Co) or nickel (Ni), as well as alloys of nickel (Ni) and platinum (Pt). These metals are considered mid band gap metals because they have similar contact resistance to both p-type and n-type doped silicon. In addition, these metal silicides have relatively low sheet resistance. N-type dopants may include but are not limited to: phosphorous (P), arsenic (As) and antimony (Sb), and p-type dopants may include but are not limited to: boron (B), indium (In) and gallium (Ga). Very low contact resistance may be achieved, however, using near band edge metals, such as platinum (Pt) for p-type doped silicon, and erbium (Er) or ytterbium (Yb) for n-type doped silicon. Unfortunately, these metal silicides have much higher (e.g., twice) sheet resistance compared to the commonly used cobalt or nickel silicide.

### SUMMARY

A structure including a dual silicide region and a related method are disclosed. The structure may include a doped silicon, and a dual silicide region in the doped silicon, the dual silicide region including a first silicide region including a mid band gap metal, and a second silicide region including a near band gap metal, wherein the second silicide region is immediately adjacent to the doped silicon. The method may include forming a first silicide portion in a doped silicon by depositing a first metal over the doped silicon, annealing and removing unreacted first metal; ion implanting a second metal into the doped silicon; and annealing to form a second silicide portion from the second metal, wherein the first metal is different than the second metal.

A first aspect of the disclosure includes a structure comprising: a doped silicon; and a dual silicide region in the doped silicon, the dual silicide region including a first silicide region and a second silicide region; wherein the second silicide region is immediately adjacent to the doped silicon.

A second aspect of the disclosure provides a structure comprising: a doped silicon; a dual silicide region in the doped silicon, the dual silicide region including a first silicide region including a mid band gap metal, and a second silicide region including a near band gap metal, wherein the second silicide region is immediately adjacent to the doped silicon.

A third aspect of the disclosure provides a method comprising: forming a first silicide portion in a doped silicon by depositing a first metal over the doped silicon, annealing and removing unreacted first metal; ion implanting a second metal into the doped silicon; and annealing to form a second silicide portion from the second metal, wherein the first metal is different than the second metal.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-3 show embodiments of a method according to the disclosure, with FIG. 3 showing embodiments of a structure according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

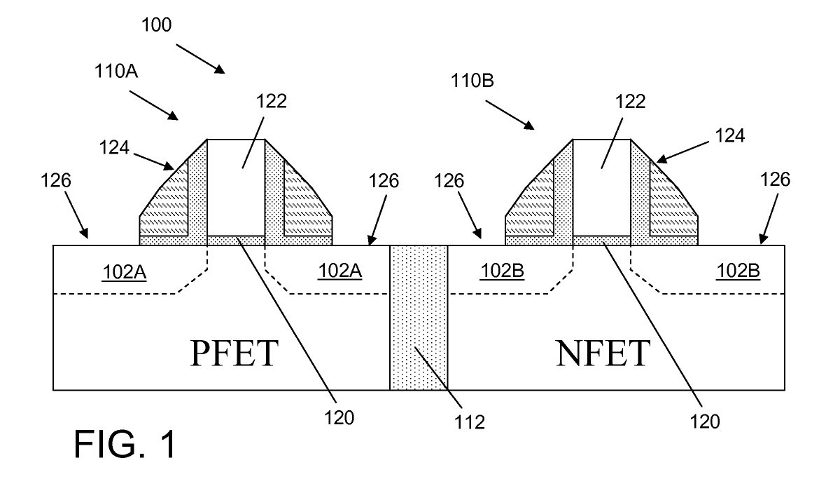

FIGS. 1-3 show embodiments of a method according to the disclosure. FIG. 1 shows an initial structure 100 including a doped silicon 102A, 102B. Structure 100 may also include transistors 110A, 110B separated by a trench isolation 112, e.g., of silicon oxide. It is understood that any number of transistors 110 separated by trench isolations 112 may be provided. Transistors 110A, 110B may include any now known or later developed structure, for example, a gate dielectric 120, a gate body or stack 122 and one or more spacers 124. Doped silicon 102A, 102B provides source/drain regions 126 for transistors 110. As illustrated, doped silicon 102A is doped with a p-type dopant, which may include but is not limited to: boron (B), indium (In) and/or gallium (Ga), and doped silicon 102B is doped with an n-type dopant, which may include but is not limited to: phosphorous (P), arsenic (As) and/or antimony (Sb). Hence, transistor 110A presents a p-type field effect transistor (PFET) and transistor 110B presents an n-type field effect transistor (NFET). Although the methods according to the disclosure will be described as applied to both transistors 110A, 110B, it is understood that the method may be applied to only one type. It is also understood that although the process will be described as applied to the different types of transistors 110A, 110B together, the materials/processes applied to the different transistors 110A, 110B may occur at different times.

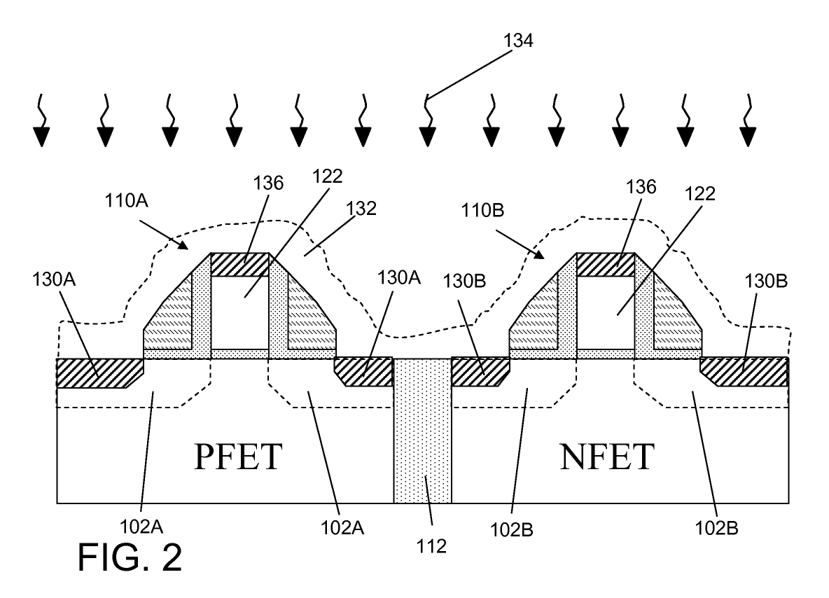

FIG. 2 shows forming a first silicide portion 130A, 130B in doped silicon 102A, 102B, respectively, by depositing a first metal 132 (in phantom) over doped silicon 102A, 102B, annealing 134 and removing unreacted first metal 132, e.g., by a reactive ion etch (RIE) or wet etch. As indicated, the process is self-aligning due to transistors 110A, 110B and isolation region(s) 112. First metal 132 may include any now known or later developed mid band gap metal such as cobalt (Co), nickel (Ni), etc. As such, first metal 132 is appropriate for both p-type doped silicon 102A and n-type doped silicon 102B, and provides a low sheet resistance. The annealing may include heating to any appropriate temperature, typically between 300° C. and 750° C., for silicidation of first metal 132. First metal 132 may be the same for transistor 110A, 110B, or different. A first silicide region 136 may also be formed in gate body or stack 122.

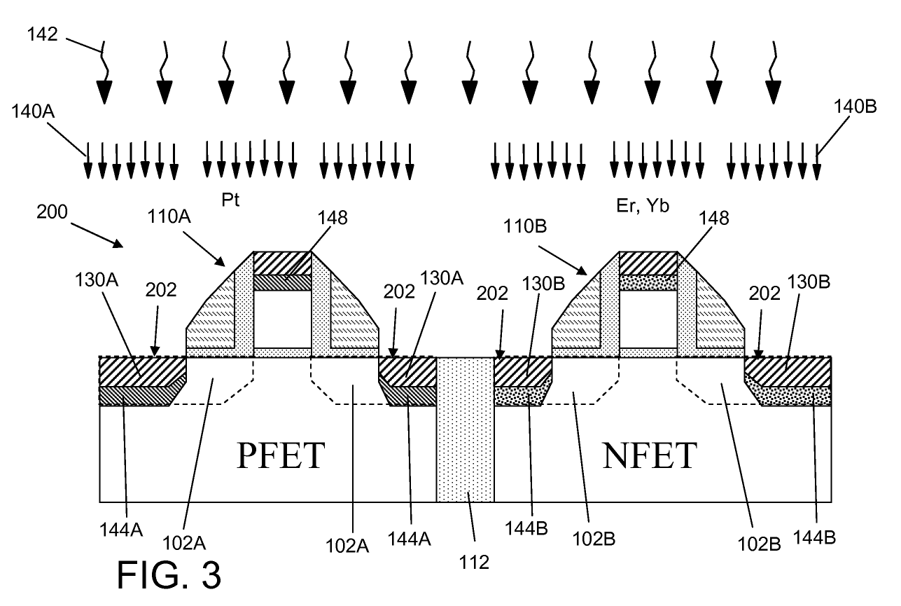

FIG. 3 shows ion implanting a second metal 140A, 140B into doped silicon 102A, 102B, respectively, and annealing 142 to form a second silicide portion 144A, 144B from the second metal. Second silicide region 144A, 144B is immediately adjacent to doped silicon 102A, 102B, respectively. First and second metals 132 and 140A, 140B are different. In one embodiment, second metal 140A, 140B includes a near band gap metal for the particular dopant of doped silicon 102A, 102B, respectively. For example, second metal 140A may include but is not limited to platinum (Pt) for p-type doped silicon 102A, and second metal 140B may include but is not limited to erbium (Er) or ytterbium (Yb) for n-type doped silicon 102B. As a result, second ion implanted silicide region 144A, 144B presents a low contact resistance with doped silicon 102A, 102B. As also shown in FIG. 3, a second silicide region 148 may also be formed for gate body or stack 122 during this process.

FIG. 3 also shows a structure 200 including doped silicon 102A and/or 102B, and a dual silicide region 202 in doped silicon 102A and/or 102B. As described herein, dual silicide region 202 includes first silicide region 130A and/or 130B including a mid band gap metal, and second (ion implanted) silicide region 144A and/or 144B including a near band gap metal. Second silicide region 144A, 144B is immediately adjacent to doped silicon 102A, 102B, respectively. In addition, first silicide region 130A, 130B has a lower sheet resistance than that of second silicide region 144A, 144B, respectively, and second silicide region 144A, 144B has a lower contact resistance than that of first silicide region 130A, 130B, respectively.

Structure 200 presents a hybrid silicide structure where the contact resistance is low because second silicide region 144A, 144B includes a near band gap metal and sheet resistance is low because first silicide region 130A, 130B (the bulk of the silicide) is a low sheet resistance metal silicide. In addition, the boundary between the NFET and PFET is connected by first silicide region 130A, 130B, which is formed on both P doped and N doped region simultaneously.

The method and structure as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A structure comprising:
a doped silicon; and
a dual silicide region in the doped silicon, the dual silicide region including a first silicide region and a second silicide region;
wherein the second silicide region is immediately adjacent to the doped silicon.

2. The structure in claim 1, wherein the first silicide region has a lower sheet resistance than that of the second silicide region.

3. The structure in claim 1, wherein the second silicide region has a lower contact resistance than that of the first silicide region.

4. A structure comprising:
a doped silicon; and
a dual silicide region in the doped silicon, the dual silicide region including a first silicide region including a mid band gap metal, and a second silicide region including a near band gap metal,
wherein the second silicide region is immediately adjacent to the doped silicon.

5. The structure of claim 4, wherein the second metal includes platinum in the case that the doped silicon includes a p-type dopant, and the second metal includes one of erbium and ytterbium in the case that the doped silicon includes an n-type dopant.

6. The structure of claim 5, wherein the first metal includes one of cobalt and nickel.

7. A method comprising:
forming a first silicide portion in a doped silicon by depositing a first metal over the doped silicon, annealing and removing unreacted first metal;
ion implanting a second metal into the doped silicon; and
annealing to form a second silicide portion from the second metal,
wherein the first metal is different than the second metal.

8. The method of claim 7, wherein the first metal includes a mid band gap metal, and the second metal includes a near band gap metal.

9. The method of claim 7, wherein the second silicide region is immediately adjacent to the doped silicon.

10. The method of claim 7, wherein the second metal includes platinum in the case that the doped silicon includes a p-type dopant, and the second metal includes one of erbium and ytterbium in the case that the doped silicon includes an n-type dopant.

11. The method of claim 10, wherein the first metal includes one of cobalt and nickel.
